(19) United States
(12) Patent Application Publication
(10) Pub. No.: US 2021/0359262 A1
(43) Pub. Date: Nov. 18, 2021

(54) ORGANIC LIGHT-EMITTING DIODE DISPLAY PANEL AND MANUFACTURING METHOD THEREOF

(71) Applicant: WUHAN CHINA STAR OPTOELECTRONICS SEMICONDUCTOR DISPLAY TECHNOLOGY CO., LTD, Wuhan, Hubei (CN)

(72) Inventor: Jiajia SUN, Wuhan, Hubei (CN)

(73) Assignee: WUHAN CHINA STAR OPTOELECTRONICS SEMICONDUCTOR DISPLAY TECHNOLOGY CO., LTD, Wuhan, Hubei (CN)

(21) Appl. No.: 16/615,873

(22) PCT Filed: Sep. 17, 2019
(86) PCT No.: PCT/CN2019/106129

§ 371 Date: Nov. 22, 2019

(30) Foreign Application Priority Data
May 27, 2019 (CN) 201910443754.7

(51) Int. Cl. H01L 51/52; H01L 27/32; H01L 51/00; H01L 51/56

(52) U.S. Cl. CPC H01L 51/5253; H01L 27/3234; H01L 27/3246; H01L 2227/323; H01L 51/0096; H01L 51/56; H01L 27/3258

(57) ABSTRACT

An organic light-emitting diode (OLED) display panel and a manufacturing method thereof are provided. The OLED display panel includes a through hole. The through hole includes a first hole and a second hole. The first hole is cut through a portion of layers exposing exposed by a sidewall of the through hole, thereby preventing moisture from entering the OLED display panel through the sidewall of the through hole. The second hole extends through a substrate to ensure clear imaging of a camera under a screen.

### FIELD OF DISCLOSURE

The present disclosure relates to the field of display technologies, and in particular, to an organic light-emitting diode (OLED) display panel and a manufacturing method thereof.

### BACKGROUND

There is a new O-cut OLED display panel, which features an O-shaped hole provided on its non-edge display area. Cameras, infrared sensors, earpieces, etc. can be placed under this 0-shaped hole. Since a position of the O-shaped hole can be optionally set, a flexibility of setting a compressed ultrafast photography (CUP, i.e., an camera positioned under the screen), the infrared sensor, the earpiece, and the like in the display area of the panel can be realized. However, due to the OLED panel includes many layers, after an external light passes through the O-cut area, a light loss is large, so that the CUP is incapable of clearly imaging. Therefore, how to improve a light transmittance of the O-cut region has become a necessary and practical research topic.

In order to solve such problems, in the prior art, after completing an array and emissive layer (EL) processes, an EL material around and separated by a distance of the O-cut region is removed by etching. Then, a thin film transistor (TFT) process is accomplished. Finally, film layers in the O-cut area are removed by laser or etching. This solution improves the light transmittance of this area by opening a hole in the O-cut area. However, this solution only considers cutting off a moisture channel of the EL film layer on a side of the O-cut hole, and ignores organic film layers such as a planarization layer (PLN) and a pixel definition layer (PDL). Therefore, external moisture can still directly enter an inside of the OLED device through the exposed PLN and PDL from the side of the O-cut hole, thereby causing a function of the OLED device to fail.

### SUMMARY OF DISCLOSURE

Since the layer is cut off at a side wall of the hole of the display panel, so that the external moisture directly enters the inside of the display panel by the cut layer on the side wall, thereby causing the function of the device inside the display panel to fail.

In order to solve the above problems, the technical solutions provided by the present disclosure are as follows.

An organic light-emitting diode (OLED) display panel includes an array substrate, a light-emitting device layer disposed on a surface of the array substrate, and an encapsulation layer disposed on the light-emitting device layer and the array substrate;

The OLED display panel includes a through hole, and the through hole passes through the array substrate, the light-emitting device layer, and the encapsulation layer.

The through hole includes a first hole and a second hole which are stacked with each other, and a diameter of the first hole is greater than a diameter of the second hole. At an edge of the through hole, the first hole is cut through the light-emitting device layer and a moisture transporting layer arranged in a thickness direction.

The array substrate includes a thin film transistor (TFT) device layer, a planarization layer disposed on the TFT device layer, and a pixel definition layer disposed on the planarization layer; and the pixel definition layer includes a plurality of pixel areas arranged in an array, and the light-emitting device layer is correspondingly disposed in the pixel areas.

The moisture transporting layer includes the planarization layer and the pixel definition layer.

In one embodiment of the present disclosure, the TFT device layer includes a TFT device and a functional layer covering the TFT device.

The first hole is cut through the light-emitting device layer, the moisture transporting layer, and a partial or entire the functional layer.

In one embodiment of the present disclosure, the encapsulation layer includes an organic layer and an inorganic layer which are alternately disposed, and the organic layer is encapsulated in the inorganic layer.

In one embodiment of the present disclosure, the inorganic layer continuously covers surfaces of the light-emitting device layer and the first hole.

In one embodiment of the present disclosure, the organic layer covers the light-emitting device layer except the through hole.

In one embodiment of the present disclosure, the organic layer covers the light-emitting device layer except the through hole and a partial or entire a surface of the first hole.

An organic light-emitting diode (OLED) display panel includes an array substrate, a light-emitting device layer disposed on a surface of the array substrate, and an encapsulation layer disposed on the light-emitting device layer and the array substrate;

The OLED display panel includes a through hole, and the through hole passes through the array substrate, the light-emitting device layer, and the encapsulation layer.

The through hole includes a first hole and a second hole which are stacked with each other, and a diameter of the first hole is greater than a diameter of the second hole. At an edge of the through hole, the first hole is cut through the light-emitting device layer and a moisture transporting layer arranged in a thickness direction.

In one embodiment of the present disclosure, the array substrate includes a thin film transistor (TFT) device layer, a planarization layer disposed on the TFT device layer, and a pixel definition layer disposed on the planarization layer; and the pixel definition layer includes a plurality of pixel areas arranged in an array, and the light-emitting device layer is correspondingly disposed in the pixel areas.

The moisture transporting layer includes the planarization layer and the pixel definition layer.

In one embodiment of the present disclosure, the TFT device layer includes a TFT device and a functional layer covering the TFT device.

The first hole is cut through the light-emitting device layer, the moisture transporting layer, and a partial or entire the functional layer.

In one embodiment of the present disclosure, the encapsulation layer includes an organic layer and an inorganic layer which are alternately disposed, and the organic layer is encapsulated in the inorganic layer.

In one embodiment of the present disclosure, the inorganic layer continuously covers surfaces of the light-emitting device layer and the first hole.

In one embodiment of the present disclosure, the organic layer covers the light-emitting device layer except the through hole.

In one embodiment of the present disclosure, the organic layer covers the light-emitting device layer except the through hole and a partial or entire a surface of the first hole.

In one embodiment of the present disclosure, a shape of the second hole includes a circular shape, an elliptic shape, or a polygonal shape.

In one embodiment of the present disclosure, the TFT device is disposed away from the through hole.

A manufacturing method of an organic light-emitting diode (OLED) display panel includes the steps as follow.

S10, providing a substrate, forming an opening area on a surface of the substrate, and performing a thickness reduction process on the opening area;

S20, forming a thin film transistor (TFT) device layer, a light-emitting device layer, and an internal layer on the substrate, where the light-emitting device layer and the internal layer are disposed on the TFT device layer, and a TFT device of the TFT device layer is disposed away from the opening area, and a recess is formed on the TFT device layer, the light-emitting device layer, and the internal layer at the opening area;

S30, removing at least the light-emitting device layer from an edge of the recess;

S40, forming an encapsulation layer on the substrate, where the encapsulation layer continuously covers surfaces of the light-emitting device layer and the recess; and

S50, removing a bottom of the recess to form a through hole.

In one embodiment of the present disclosure, in the step S30, the internal layer is further removed, and a region from which the layers is removed forms an annular step at the edge of the recess.

In one embodiment of the present disclosure, the internal layer includes at least a pixel definition layer and a planarization layer.

In one embodiment of the present disclosure, the TFT device layer includes a TFT device and a functional layer covering the TFT device.

In one embodiment of the present disclosure, the removed layer also includes a partial or entire the functional layer.

The present disclosure cuts off the layers surrounding the through hole, so that a moisture intrusion channel on the side of the through hole is cut off. Thus, an encapsulation reliability of the OLED device is ensured, and a light transmittance of the through hole is improved, thereby ensuring clear imaging of the camera positioned under the screen.

### BRIEF DESCRIPTION OF DRAWINGS

FIG. 1a is a schematic diagram showing a planar structure of an OLED display panel of an embodiment of the present disclosure.

FIG. 1b is a cross-sectional view of a hole of the OLED display panel of the embodiment of the present disclosure.

FIG. 1c is a flowchart of a manufacturing method of the OLED display panel of the embodiment of the present disclosure.

FIG. 1d is a schematic diagram showing a process of the OLED display panel of the embodiment of the present disclosure.

FIG. 1e is a schematic diagram showing another process of the OLED display panel of the embodiment of the present disclosure.

FIG. if is a schematic diagram showing another process of the OLED display panel of the embodiment of the present disclosure.

FIG. 1g is a schematic diagram showing another process of the OLED display panel of the embodiment of the present disclosure.

FIG. 2 is a schematic diagram of an OLED display panel of another embodiment of the present disclosure.

FIG. 3 is a schematic diagram of an OLED display panel of another embodiment of the present disclosure.

### DETAILED DESCRIPTION

The following embodiments are referring to the accompanying drawings for exemplifying specific implementable embodiments of the present disclosure. Furthermore, directional terms described by the present disclosure, such as upper, lower, front, back, left, right, inner, outer, side and etc., are only directions by referring to the accompanying drawings, and thus the used directional terms are used to describe and understand the present disclosure, but the present disclosure is not limited thereto. In the drawings, similar structural units are designated by the same reference numerals.

In an existing OLED display panel, a hole of a display panel is required, but a side of the hole of the display panel is not completely protected, resulting in a technical defect of moisture intruding into the OLED panel. The present disclosure can solve this defect.

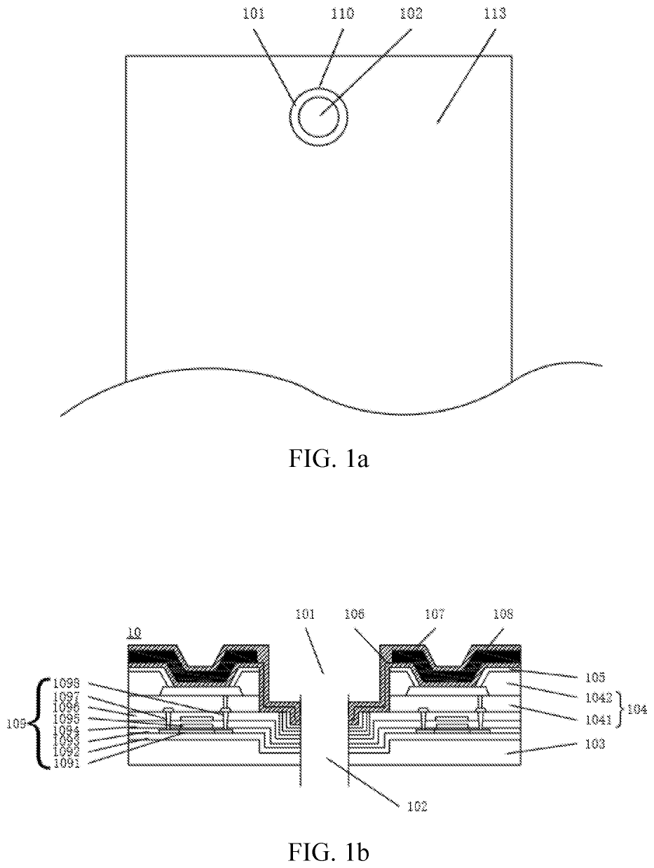

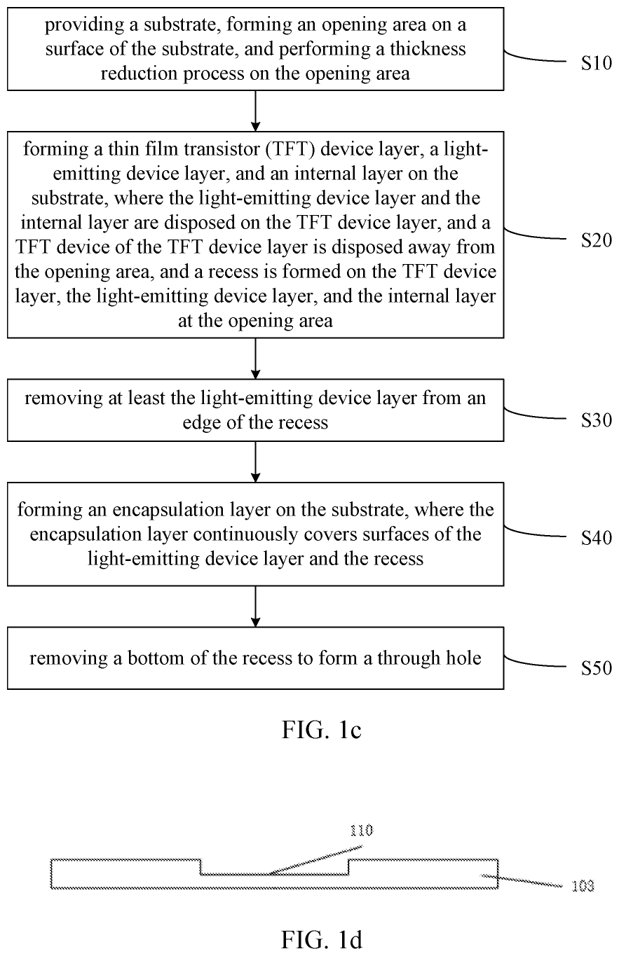

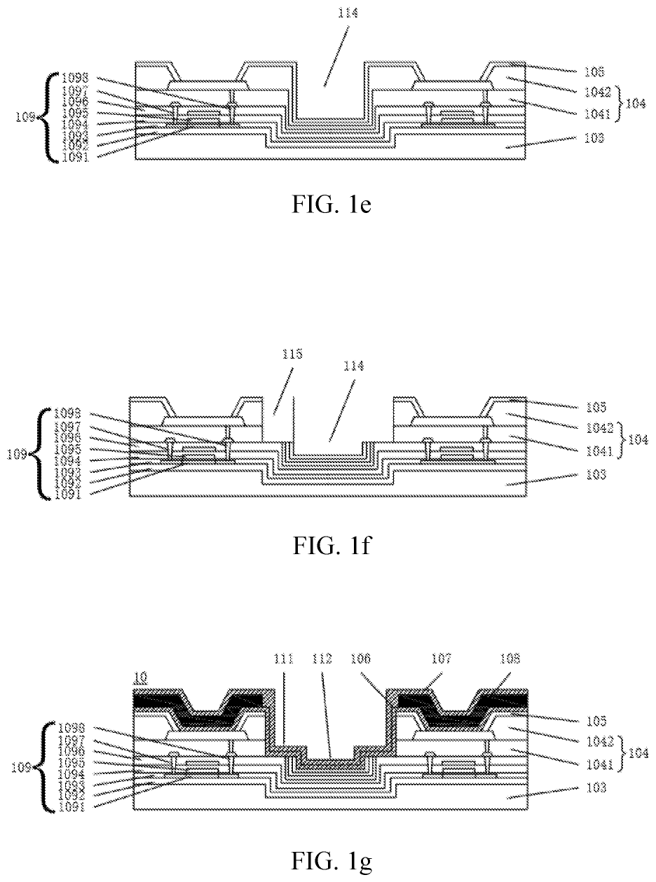

FIG. 1a and FIG. 1b are a plan view and cross-sectional view of a hole structure of the present disclosure. The present disclosure provides an OLED display panel. The display panel 10 includes an array substrate, a light-emitting device layer 105 disposed on a surface of the array substrate, and an encapsulation layer disposed on the light-emitting device layer 105 and the array substrate.

The array substrate includes a substrate 103, a TFT device layer 109, and an internal layer 104, and the TFT device layer 109 and the internal layer 104 are disposed on the substrate 103. The internal layer 104 includes at least a planarization layer 1041 and a pixel definition layer 1042. The TFT device layer 109 further includes an active layer 1091, a buffer layer 1092, gate insulating layers 1093 and 1094, a gate 1095, an intermediate dielectric layer 1096, and source and drain 1097 and 1098. Specifically, layers on the substrate 103 are the buffer layer 1092, the gate insulating layers 1093 and 1094, the intermediate dielectric layer 1096, the planarization layer 1041, and the pixel definition layer 1042 which are sequentially stacked from bottom-to-top. The pixel definition layer 1042 includes a plurality of pixel areas arranged in an array. The light-emitting device layer 105 is correspondingly disposed in the pixel areas. The active layer 1091 is disposed on the buffer layer 1092 and covered by the gate insulating layer 1093. The gate 1095 is disposed on the gate insulating layer 1093 and covered by the gate insulating layer 1094. The gate 1095 is located above the active layer 1091. The source and drains 1097 and 1098 are respectively disposed on both sides of the active layer 1091 and extend through the gate insulating layers 1093 and 1094 and the intermediate dielectric layer 1096. The display panel 10 includes an opening area 110. A through hole is formed on the opening area 110. Therefore, TFT devices of the TFT device layer 109 are disposed outside the opening area 110. Each of the TFT devices includes the active layer 1091, the gate 1095, and source and drain 1097 and 1098.

In addition, the through hole in the opening area 110 is a stepped hole. The stepped hole includes a first hole 101 and a second hole 102 which are stacked with each other. The first hole 101 is adjacent to the light-emitting device layer 105. A diameter of the first hole 101 is greater than a diameter of the second hole 102. At an edge of the through hole, the first hole 101 is cut through the light-emitting device layer 105 and a moisture transporting layer disposed on the light-emitting device layer 105 in a thickness direction.

Preferably, the moisture transporting layer includes the planarization layer 1041 and the pixel definition layer 1042.

Preferably, the first hole may be cut through a partial or entire the light-emitting device layer 105, the planarization layer 1041, the pixel definition layer 1042, and the TFT device layer.

Preferably, a planar shape of the second hole 102 includes a circular shape, an elliptic shape, or a polygonal shape. A cross-sectional shape of the second hole 102 includes a square shape, an inverted trapezoidal shape, or an arc shape.

Preferably, the first hole 101 and the second hole 102 can be fabricated by using a laser technology and an etching technique.

The encapsulation layer includes an organic layer and an inorganic layer which are alternatively disposed, and the encapsulation layer covers the light-emitting device layer 105, the first hole 101, and a portion of the second hole 102.

The organic layer is encapsulated in the inorganic layer. The inorganic layer covers the light-emitting device layer 105, the first hole 101, and a portion of the second hole 102. An extension region of the organic layer is less than or equal to an extension region of the inorganic layer, and does not exceed a boundary at which the first hole 101 and the second hole 102 are connected. That is, the organic layer may cover only a surface of the light-emitting device layer 105 except the opening area 110, or the organic layer may cover the surface of the light-emitting device layer 105 except the opening area 110 and a partial surface of the stepped hole.

Preferably, the inorganic layer covers a layer above the second hole 102 in a direction perpendicular to a surface of the panel.

Preferably, the encapsulation layer will cover at least the light-emitting device layer 105, the pixel definition layer 1042, and the planarization layer 1041 in a sidewall of the first hole 101. A moisture intrusion channel of the light-emitting device layer 105, the pixel definition layer 1042, and the planarization layer 1041 on the sidewall of the opening area 110 is cut off, thereby protecting the OLED display panel from moisture intrusion.

That is, the encapsulation layer may cover any of the layers below the intermediate dielectric layer 1096 to prevent moisture intrusion.

In the embodiment of the present disclosure:

The first hole 101 will be cut through the light-emitting device layer 105, the pixel definition layer 1042, and the planarization layer 1041 at an edge of the opening area 110.

That is, the sidewall of the first hole 101 includes the light-emitting device layer 105, the pixel definition layer 1042, and the planarization layer 1041.

The encapsulation layer includes a first inorganic layer 106, a first organic layer 108, and a second inorganic layer 107 which are disposed layer-by-layer.

The first organic layer 108 is disposed between the first inorganic layer 106 and the second inorganic layer 107 and is completely covered by the first inorganic layer 106 and the second inorganic layer 107. All of boundaries of the first organic layer 108 are covered.

The first inorganic layer 106 will cover the surface of the light-emitting device layer 105 and cover a partial surface of the stepped hole. The partial surface of the stepped hole includes a surface of the first hole 101 and a surface of the second hole 102 in a direction perpendicular to a surface of the panel.

That is, the light-emitting device layer 105, the pixel definition layer 1042, and the planarization layer 1041 at the sidewall of the first hole 101 are covered.

The first organic layer 108 covers the surface of the light-emitting device layer 105 except the opening area 110, that is, the opening area 110 is not covered.

The second inorganic layer 107 completely covers the first organic layer 108 and the first inorganic layer 106.

In summary, the encapsulation layer can protect the side of the opening area 110 to prevent moisture intrusion. Moreover, the encapsulation layer will cover at least the light-emitting device layer 105, the planarization layer 1041, and the pixel definition layer 1042, to solve the technical problem in the prior art that a moisture is intruded from the light-emitting device layer 105, the planarization layer 1041, and the pixel definition layer 1042 into an inside of the OLED display panel.

FIG. 1c is a flowchart of a method of the present disclosure, where the method includes the following steps.

S10, a substrate 103 is provided, and an opening area 110 is formed on a surface of the substrate 103, and a thickness reduction process is performed on the opening area 110.

S20, a thin film transistor (TFT) device layer 109, a light-emitting device layer 105, and an internal layer 104 are formed on the substrate 103, where the light-emitting device layer 105 and the internal layer 104 are disposed on the TFT device layer 109. TFT devices of the TFT device layer 109 are disposed away from the opening area 110. A recess 114 is formed on the TFT device layer 109, the light-emitting device layer 105, and the internal layer 104 at the opening area 110.

S30, at least the light-emitting device layer 105 are removed from an edge of the recess 114.

S40, an encapsulation layer is formed on the substrate 103. The encapsulation layer continuously covers surfaces of the light-emitting device layer 105 and the recess 114.

S50, a bottom of the recess 114 is removed to form a through hole.

As shown in FIG. 1d, FIG. 1e, FIG. 1f, and FIG. 1g, schematic diagrams of processes of a manufacturing method of an OLED display panel of a preferred embodiment of the present disclosure are shown. The method steps of the embodiment are specifically described below.

S10, as shown in FIG. 1c, a substrate 103 is provided, and an opening area 110 is formed on the substrate 103, and a thickness reduction process is performed on the opening area 110 of the substrate 103. The reduced thickness is less than a thickness of the substrate 103.

S20, as shown in FIG. 1d, a TFT device layer 109, a light-emitting device layer 105, and an internal layer 104 are formed on the substrate 103 according to a normal process. The internal layer 104 further includes a planarization layer 1041 and a pixel definition layer 1042. The TFT device layer 109 further includes an active layer 1091, a buffer layer 1092, gate insulating layers 1094 and 1094, a gate 1095, an intermediate dielectric layer 1096, and source and drain 1097 and 1098.

It should be noted that since the opening area 110 is subjected to the thickness reduction process, a recess 114 is formed in the opening area of the above layers.

S30, as shown in FIG. 1e, an edge of the recess 114 (i.e., the light-emitting device layer 105, the planarization layer 1041, and the pixel definition layer 1042 between a boundary of the recess 114 and a boundary of the opening area 110) is removed using a laser technique or an etching technique to form an annular step 115.

It should be noted that the removed layers includes at least the light-emitting device layer 105, and the planarization layer 1041 and the pixel definition layer 1042, that is any of layers below the intermediate dielectric layers 1096 may be removed.

S40, as shown in FIG. 1f, an encapsulation layer is formed on the substrate 103 according to a normal process. The encapsulation layer includes a first inorganic layer 106, a first organic layer 108, and a second inorganic layer 107.

It should be noted that the first organic layer 108 is disposed between the first inorganic layer 106 and the second inorganic layer 107 and is completely covered by the first inorganic layer 106 and the second inorganic layer 107.

In addition, the encapsulation layer will form two different depths of recesses in the opening area 110 due to the thickness reduction process of step S1 and the layer removal process of step S3. That is, a periphery of the opening area 110 forms an annular platform portion 111 and a recess 112 having a larger depth and surrounded by the annular platform portion 111.

S50, the layers at the bottom of the recess 114 (i.e., the bottom of the recess 112) and the substrate 103 are removed by using a laser technology or an etching technique to form a through hole, thereby obtaining a hole structure as shown in FIG. 1b.

The first inorganic layer 106 and the second inorganic layer 107 may cover all areas except the second hole 102 to prevent moisture intrusion.

An edge of the first organic layer 108 may extend to any position of an extension region of the first inorganic layer 106, but not beyond the boundary of the recess 112 (i.e., not exceed the boundary of the second hole 102).

FIG. 2 shows a preferred embodiment of the present disclosure, which differs from FIG. 1b in an extension region of the first organic layer 206.

In this embodiment, an encapsulation layer includes a first inorganic layer 205, a first organic layer 206, and a second inorganic layer 207.

A sidewall of the first hole 201 includes a light-emitting device layer 204, a pixel definition layer 203, and a planarization layer 202. The encapsulation layer covers the above three organic layers to prevent the moisture from intruding into the OLED display panel through the above three layers.

The first organic layer 206 will cover a surface of the light-emitting device layer 204 and a partial or entire the first hole 201.

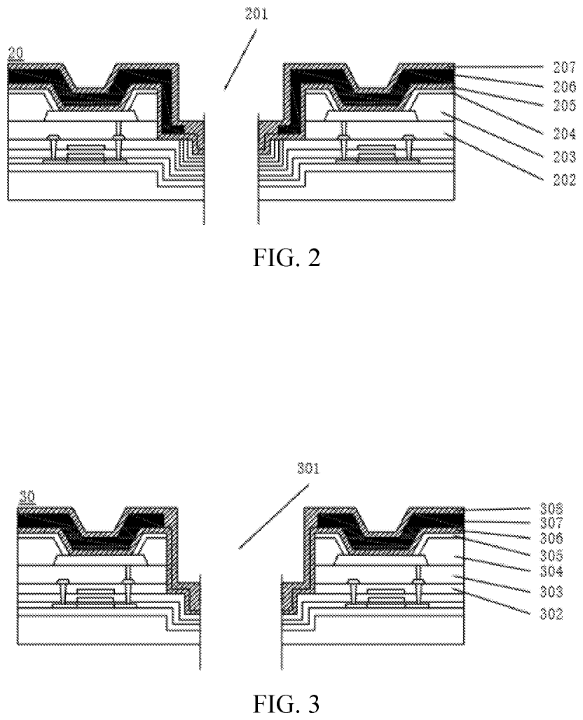

FIG. 3 shows another preferred embodiment of the present disclosure, which differs from FIG. 1b in a depth of the first hole 301.

In this embodiment, an encapsulation layer includes a first inorganic layer 306, a first organic layer 307, and a second inorganic layer 308 which are disposed layer-by-layer.

A sidewall of a first hole 301 includes a light-emitting device layer 305, a pixel definition layer 304, a planarization layer 303, and a gate insulating layer 302.

The encapsulation layer covers the light-emitting device layer 305, the pixel definition layer 304, the planarization layer 303, and the gate insulating layer 302 to prevent the moisture from intruding into the OLED display panel through the above four layers.

The first organic layer 307 covers only a surface of the light-emitting device layer 305.

The present disclosure cuts off the layers surrounding the through hole, so that a moisture intrusion channel on the side of the through hole is cut off. Thus, an encapsulation reliability of the OLED device is ensured, and a light transmittance of the through hole is improved, thereby ensuring clear imaging of the camera positioned under the screen.

In conclusion, although the present disclosure has been described with reference to the preferred embodiments thereof, it is apparent to those skilled in the art that a variety of modifications and changes may be made without departing from the scope of the present disclosure which is intended to be defined by the appended claims.

What is claimed is:

1. An organic light-emitting diode (OLED) display panel, comprising: an array substrate, a light-emitting device layer disposed on a surface of the array substrate, and an encapsulation layer disposed on the light-emitting device layer and the array substrate;
wherein the OLED display panel comprises a through hole, and the through hole passes through the array substrate, the light-emitting device layer, and the encapsulation layer;
wherein the through hole comprises a first hole and a second hole which are stacked with each other, and a diameter of the first hole is greater than a diameter of the second hole; wherein at an edge of the through hole, the first hole is cut through the light-emitting device layer and a moisture transporting layer arranged in a thickness direction;
wherein the array substrate comprises a thin film transistor (TFT) device layer, a planarization layer disposed on the TFT device layer, and a pixel definition layer disposed on the planarization layer; wherein the pixel definition layer comprises a plurality of pixel areas arranged in an array, and the light-emitting device layer is correspondingly disposed in the pixel areas; and
wherein the moisture transporting layer comprises the planarization layer and the pixel definition layer.

2. The OLED display panel as claimed in claim 1, wherein the TFT device layer comprises a TFT device and a functional layer covering the TFT device; and
the first hole is cut through the light-emitting device layer, the moisture transporting layer, and a partial or entire the functional layer.

3. The OLED display panel as claimed in claim 1, wherein the encapsulation layer comprises an organic layer and an inorganic layer which are alternately disposed, and the organic layer is encapsulated in the inorganic layer.

4. The OLED display panel as claimed in claim 3, wherein the inorganic layer continuously covers surfaces of the light-emitting device layer and the first hole.

5. The OLED display panel as claimed in claim 4, wherein the organic layer covers the light-emitting device layer except the through hole.

6. The OLED display panel as claimed in claim 4, wherein the organic layer covers the light-emitting device layer except the through hole and a partial or entire a surface of the first hole.

7. An organic light-emitting diode (OLED) display panel, comprising: an array substrate, a light-emitting device layer disposed on a surface of the array substrate, and an encapsulation layer disposed on the light-emitting device layer and the array substrate;
wherein the OLED display panel comprises a through hole, and the through hole passes through the array substrate, the light-emitting device layer, and the encapsulation layer; and
wherein the through hole comprises a first hole and a second hole which are stacked with each other, and a diameter of the first hole is greater than a diameter of the second hole; wherein at an edge of the through hole, the first hole is cut through the light-emitting device layer and a moisture transporting layer arranged in a thickness direction.

8. The OLED display panel as claimed in claim 7, wherein the array substrate comprises a thin film transistor (TFT) device layer, a planarization layer disposed on the TFT device layer, and a pixel definition layer disposed on the planarization layer; wherein the pixel definition layer comprises a plurality of pixel areas arranged in an array, and the light-emitting device layer is correspondingly disposed in the pixel areas; and
wherein the moisture transporting layer comprises the planarization layer and the pixel definition layer.

9. The OLED display panel as claimed in claim 8, wherein the TFT device layer comprises a TFT device and a functional layer covering the TFT device; and
the first hole is cut through the light-emitting device layer, the moisture transporting layer, and a partial or entire the functional layer.

10. The OLED display panel as claimed in claim 7, wherein the encapsulation layer comprises an organic layer and an inorganic layer which are alternately disposed, and the organic layer is encapsulated in the inorganic layer.

11. The OLED display panel as claimed in claim 10, wherein the inorganic layer continuously covers surfaces of the light-emitting device layer and the first hole.

12. The OLED display panel as claimed in claim 11, wherein the organic layer covers the light-emitting device layer except the through hole.

13. The OLED display panel as claimed in claim 11, wherein the organic layer covers the light-emitting device layer except the through hole and a partial or entire a surface of the first hole.

14. The OLED display panel as claimed in claim 7, wherein a shape of the second hole comprises a circular shape, an elliptic shape, or a polygonal shape.

15. The OLED display panel as claimed in claim 9, wherein the TFT device is disposed away from the through hole.

16. A manufacturing method of an organic light-emitting diode (OLED) display panel, comprising:
S10, providing a substrate, forming an opening area on a surface of the substrate, and performing a thickness reduction process on the opening area;
S20, forming a thin film transistor (TFT) device layer, a light-emitting device layer, and an internal layer on the substrate, wherein the light-emitting device layer and the internal layer are disposed on the TFT device layer, and a TFT device of the TFT device layer is disposed away from the opening area, and a recess is formed on the TFT device layer, the light-emitting device layer, and the internal layer at the opening area;
S30, removing at least the light-emitting device layer from an edge of the recess;
S40, forming an encapsulation layer on the substrate, wherein the encapsulation layer continuously covers surfaces of the light-emitting device layer and the recess; and
S50, removing a bottom of the recess to form a through hole.

17. The manufacturing method of the OLED display panel as claimed in claim 16, wherein in the step S30, the internal layer is further removed, and a region from which the layers is removed forms an annular step at the edge of the recess.

18. The manufacturing method of the OLED display panel as claimed in claim 17, wherein the internal layer comprises at least a pixel definition layer and a planarization layer.

19. The manufacturing method of the OLED display panel as claimed in claim 16, wherein the TFT device layer comprises a TFT device and a functional layer covering the TFT device.

20. The manufacturing method of the OLED display panel as claimed in claim 19, wherein the removed layer also comprises a partial or entire the functional layer.
